(19) United States
(12) Patent Application Publication
(10) Pub. No.: US 2001/0015916 A1
(43) Pub. Date: Aug. 23, 2001

(54) STORAGE CELLS UTILIZING REDUCED PASS GATE VOLTAGES FOR READ AND WRITE OPERATIONS

(76) Inventor: EDDY CHIEH HUANG, SAN JOSE, CA (US)

Correspondence Address: MCCUTCHEN DOYLE BROWN & ENERSEN, THREE EMBARCADERO CENTER, SAN FRANCISCO, CA, 94111

(21) Appl. No.: 09/231,998

(22) Filed: Jan. 15, 1999

(51) Int. Cl. G11C 7/00

(52) U.S. Cl. 365/189.11; 365/1

(57) ABSTRACT

A data storage apparatus includes a latch having first and second storage nodes, a first pass transistor coupled to the first storage node, a row line coupled to a gate of the first pass transistor, and a row driver coupled to the row line. The row driver is configured to drive the row line to three different voltage levels. The three different voltage levels included a low logic level voltage, a full supply high voltage level, and a reduced high voltage level. The reduced high voltage level is greater than the low logic level voltage and less than the full supply high voltage level. A method of manipulating a memory cell having a latch having a first storage node with first and second series connected pass transistors coupled to the first storage node and a bit line coupled to the second pass transistor, includes driving the bit line to a low logic level voltage; applying a full supply high voltage level to a gate of the first pass transistor and to a gate of the second pass transistor; applying the low logic level voltage to the gate of the first pass transistor and to the gate of the second pass transistor; precharging the bit line to a high level; and applying a reduced high voltage level to the gate of the first pass transistor and to the gate of the second pass transistor, wherein the reduced high voltage level is greater than the low logic level voltage and less than the full supply high voltage level.

### BACKGROUND OF THE INVENTION

1. Field of the Invention

The present invention relates to programmable logic devices, and more particularly, to reading and writing data to SRAM storage cells having one bit line.

2. Description of the Related Art

Referring to FIG. 1, there is illustrated a typical CMOS static random access memory (SRAM) cell 10. The cell 10 includes two n-channel pass transistors M2, M4 (or “pass gates”) and two inverters 12, 14 connected back-to-back to form a latch 28. The inverter 12 includes a p-channel transistor M6 and an n-channel transistor M8, and the inverter 14 includes a p-channel transistor M10 and an n-channel transistor M12. Pass transistor M2 is used to connect storage node 16 of the latch 28 to a bit line 20, and pass transistor M4 is used to connect storage node 18 of the latch 28 to a complimentary bit line 22. Pass transistors M2, M4 are activated, or turned on, by a row line signal 24.

The SRAM cell 10 is programmed, or written, by pulling (or driving) one of the storage nodes 16 or 18 to low, which in turn renders the other storage node 16 or 18 high by the latch operation. Specifically, such programming or writing is done by pulling the row line 24 high which turns on, or “opens”, pass transistors M2, M4. If the users wishes to store a “0” at storage node 16 and a “1” at storage node 18, the bit line 20 is driven low. Because pass transistor M2 is on, storage node 16 is pulled low by bit line 20, which turns on transistor M6, which pulls storage node 18 high. When storage node 18 goes high, transistor M12 turns on which keeps storage node 16 pulled low. On the other hand, if the users wishes to store a “1” at storage node 16 and a “0” at storage node 18, the complementary bit line 22 is driven low, which in a similar manner turns on transistors M10 and M8. The writing operation is completed by returning the row line 24 to low which turns off, or “closes”, pass transistors M2, M4. The latch function of the back-to-back inverters 12, 14 keeps storage nodes 16, 18 in opposite states even when the row line 24 is turned off (i.e., low). Therefore, the SRAM cell 10 can be easily written by using N-type transistors, which are inherently good pull-down devices, as the pass transistors M2, M4 for pulling down storage nodes 16, 18, respectively.

The SRAM cell 10 is read by first precharging both the bit line 20 and the complementary bit line 22 high with a weak pull-up device. The row line 24 is then pulled high to open the pass transistors M2, M4. The data that is stored at storage nodes 16, 18 is then sensed by sense amplifier circuitry (not shown) that is used to detect voltage differentials between the bit lines 20, 22.

During the read operation, if a “0” is stored at storage node 16, the bit line 20 must be pulled low from its precharged high state when pass transistor M2 is opened in order for the sense amplifier circuitry to read the data. This will occur if the pass transistor M2 is a weaker device than the pull down transistor M12, i.e., the transistor channel width-to-length ratio of pass transistor M2 is much less than the channel width-to-length ratio of transistor M12 (W_{M2}/L_{M2}<<W_{M12}/L_{M12}). If pass transistor M2 is not weaker than the pull-down transistor M12, a read operation could actually destroy the stored data. Specifically, the storage node 16 could be pulled high by the precharged bit line 20, which would result in the latch being toggled and the stored data being destroyed. By using pass transistors M2, M4 that are weaker than the pull-down transistors M8, M12, destructive disturbance during read operations is prevented.

For field programmable logic device applications, however, the SRAM cell 10 may be considered too large. For these types of applications one of the pass transistors M2 or M4 in the SRAM cell 10 is normally omitted to save the area of one bit line. This results in the cell 30 shown in FIG. 2. In the cell 30, only one storage node, storage node 16, can be accessed. Because only storage node 16 can be accessed, one needs to be able to pull storage node 16 either high or low in order to write data into the cell 30. The storage node 16 is pulled either high or low by driving the bit line 20 either high or low and opening the pass transistor M2. This is different than the cell 10 where data could be written into the cell by simply pulling one of storage nodes 16 or 18 low, i.e., pulling a storage node high was not required. In order to be able to pull storage node 16 either high or low, the N-type pass transistor M2 needs to be strong, i.e., have a large transistor channel width-to-length ratio, in order to overcome the current latch state during the write process. For example, if storage node 16 is currently a “0”, and the user wishes to write it to a “1”, the pass transistor M2 must be capable of overcoming the pull-down transistor M12. Or, if storage node 16 is currently a “1”, and the user wishes to write it to a “0”, the pass transistor M2 must be capable of overcoming the pull-up transistor M10.

But as discussed above, having a strong N-type pass transistor M2 is detrimental to the read operation. Specifically, during the read process, the bit line 20 is precharged high. If a “0” is stored at storage node 16, the strong pass transistor M2, when opened, may pull storage node 16 high, resulting in the low voltage on storage node 16 being switched to high inadvertently. Therefore, while a strong N-type pass transistor M2 is needed to perform the write operation in the cell 30, it could possibly alter the previously written state during the read operation. These conflicting requirements make the cell design difficult.

Thus, it would be desirable to have a simple, robust, and small size solution to the problem of destructive disturbance of data during read operations of storage cells having a single bit line.

### BRIEF SUMMARY OF THE INVENTION

The present invention provides a data storage apparatus. The apparatus includes a latch having first and second storage nodes, a first pass transistor coupled to the first storage node, a row line coupled to a gate of the first pass transistor, and a row driver coupled to the row line. The row driver is configured to drive the row line to three different voltage levels. The three different voltage levels included a low logic level voltage, a full supply high voltage level, and a reduced high voltage level. The reduced high voltage level is greater than the low logic level voltage and less than the full supply high voltage level.

Another version of the data storage apparatus of the present invention includes a plurality of memory cells arranged into rows and columns. Each memory cell includes a latch having first and second storage nodes and a first pass transistor coupled to the first storage node. A plurality of a row lines is included with each row line being associated with one row of memory cells and being coupled to a gate of the first pass transistor of each memory cell in its respective row. A plurality of row drivers is included with each row driver being coupled to one row line and configured to drive the one row line to three different voltage levels. The three different voltage levels includes a low logic level voltage, a full supply high voltage level, and a reduced high voltage level. The reduced high voltage level is greater than the low logic level voltage and less than the full supply high voltage level.

The present invention also provides a method of manipulating a memory cell having a latch having a first storage node with first and second series connected pass transistors coupled to the first storage node and a bit line coupled to the second pass transistor. The method includes driving the bit line to a low logic level voltage; applying a full supply high voltage level to a gate of the first pass transistor and to a gate of the second pass transistor; applying the low logic level voltage to the gate of the first pass transistor and to the gate of the second pass transistor; precharging the bit line to a high level; and applying a reduced high voltage level to the gate of the first pass transistor and to the gate of the second pass transistor, wherein the reduced high voltage level is greater than the low logic level voltage and less than the full supply high voltage level.

The present invention also provides a method of manipulating a memory cell having a latch having a first storage node with a first pass transistor coupled to the first storage node and a bit/column line coupled to the first pass transistor. The method includes applying a full supply high voltage level to the bit/column line; applying the full supply high voltage level to a gate of the first pass transistor; applying a low logic level voltage to the gate of the first pass transistor; driving the bit/column line to the low logic level voltage; and applying a reduced high voltage level to the gate of the first pass transistor, wherein the reduced high voltage level is greater than the low logic level voltage and less than the full supply high voltage level.

A better understanding of the features and advantages of the present invention will be obtained by reference to the following detailed description of the invention and accompanying drawings which set forth an illustrative embodiment in which the principles of the invention are utilized.

### BRIEF DESCRIPTION OF THE DRAWINGS

FIG. 1 is a schematic diagram illustrating a conventional CMOS static random access memory (SRAM) cell.

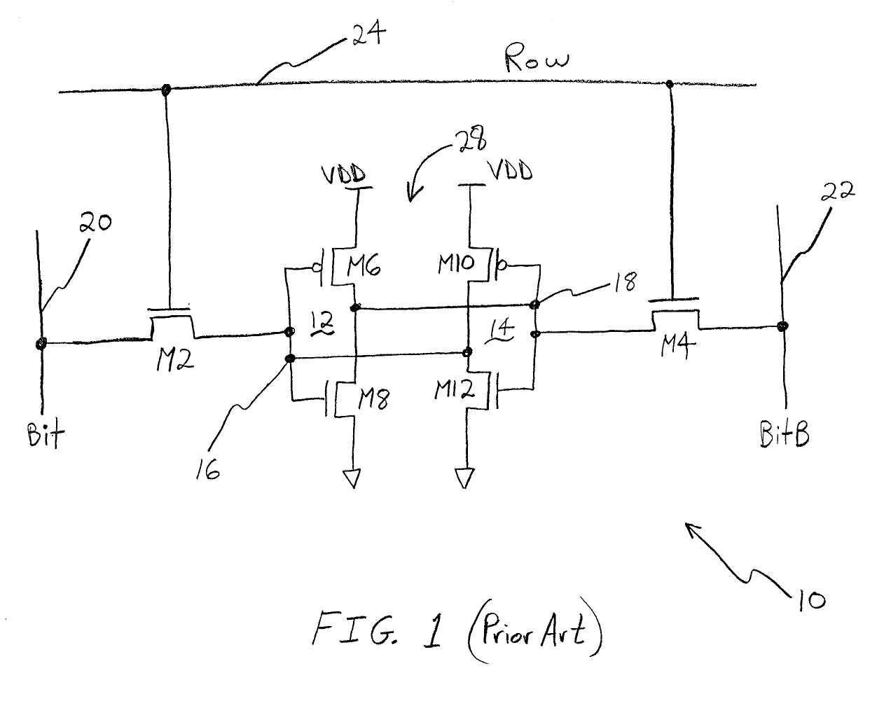

FIG. 2 is a schematic diagram illustrating a conventional CMOS SRAM cell having only one bit line.

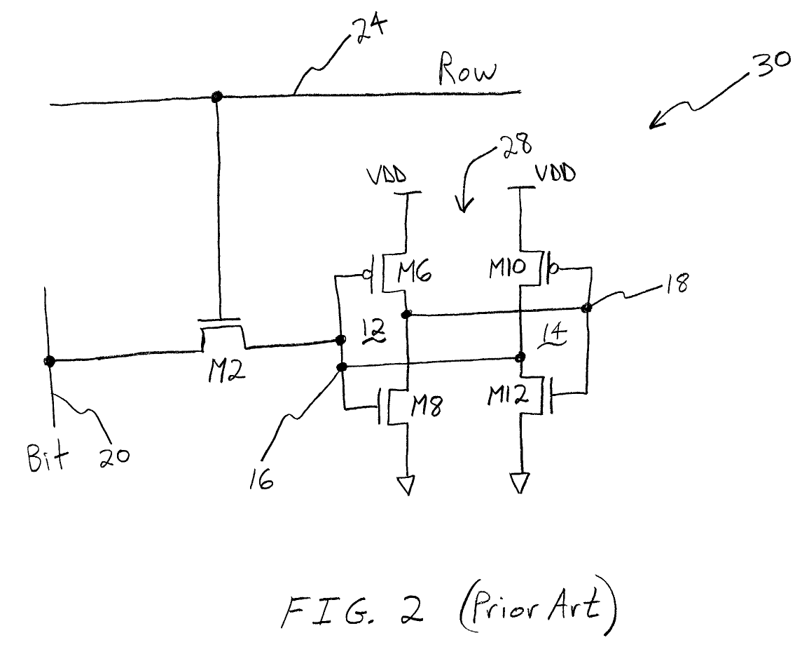

FIG. 3 is a schematic diagram illustrating a programmable logic device in accordance with the present invention.

FIG. 4 is a schematic diagram illustrating in more detail one of the storage cells shown in FIG. 3.

FIG. 5 is a schematic diagram illustrating an exemplary driver circuit that may be used for the row and column drivers shown in FIG. 3 or the row drivers shown in FIG. 6.

FIG. 6 is a schematic diagram illustrating another programmable logic device in accordance with the present invention.

FIG. 7 is a schematic diagram illustrating in more detail one of the storage cells shown in FIG. 6.

### DETAILED DESCRIPTION OF THE INVENTION

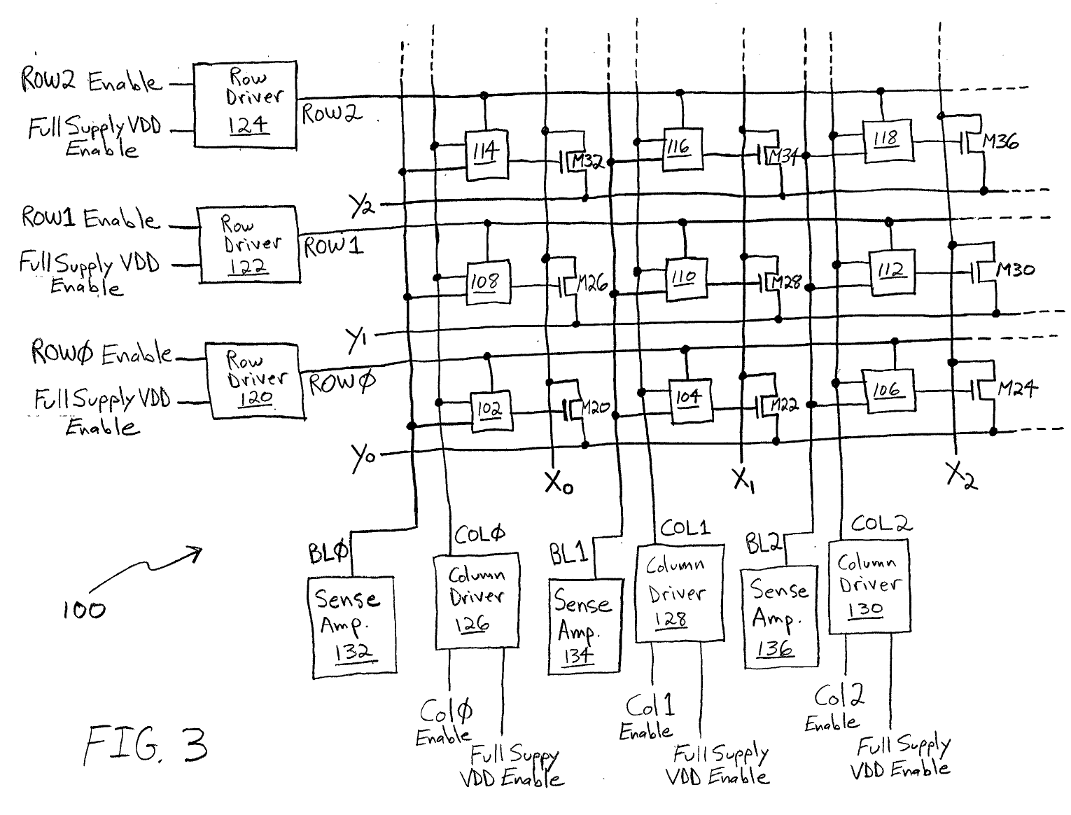

Referring to FIG. 3, there is illustrated a programmable logic device 100 in accordance with the present invention. The device 100 includes an array of several vertical signal lines X0, X1, X2, etc., and several horizontal signal lines Y0, Y1, Y2, etc. The X signal lines may be connected to the Y signal lines by means of connection n-channel transistors M20-M36. For example, signal line X0 is connected to signal line Y0 when transistor M20 is turned on, signal line X2 is connected to signal line Y1 when transistor M30 is turned on, signal line X1 is connected to signal line Y2 when transistor M34 is turned on, etc. The connection transistors M20-M36 are turned on and off by corresponding storage (or memory) cells 102-118, respectively. When a storage cell stores a “1”, its corresponding connection transistor is turned on, and when a storage cell stores a “0”, its corresponding connection transistor is turned off. The connection transistors M20-M36 and corresponding storage cells 102-118 allow programmable connections to be made between the X signal lines and the Y signal lines such that a user can selectively determine the inputs to an array of logic gates, e.g., AND, OR, etc., that may be connected to either the X or Y signal lines. Thus, the connection transistors M20-M36 can be used to implement programmable connections in a logic array within a field programmable logic device. The same scheme can also be used to configure logic functions. For example, storage cells may be used inside functional blocks to configure logic functions such as, for example, addition, subtraction, etc., inside of a field programmable logic device.

In a field programmable logic device, such as the device 100, data is written into the storage cells 102-118 for the purpose of clearing all connections between the X and Y signal lines, i.e., a “memory clear” operation, and for programming specific connections between the X and Y signal lines, i.e., “configuring” the device 100. The read operation in the device 100 is used for example for testing purposes, but is used less frequently than the write operation. Although it is used less frequently, the read operation is nevertheless an important operation.

The device 100 is a two dimensionally addressable array. Specifically, during either a write operation or a read operation a specific storage cell may be selected by the use of the row lines ROW0, ROW1, ROW2, etc. and the column lines COL0, COL1, COL2, etc. For example, by activating ROW1 and COL0, storage cell 108 is selected; by activating ROW2 and COL1, storage cell 116 is selected; by activating ROW2 and COL2, storage cell 118 is selected; etc. In this way, a specific storage cell can be written or read. All of the storage cells may be written to simultaneously (e.g., a clear memory operation) by activating all of the row and column lines. During read operations, stored data may be sensed by sense amplifiers 132, 134, 136. Specifically, the sense amplifier 132 senses data on bit line BL0, the sense amplifier 134 senses data on bit line BL1, the sense amplifier 136 senses data on bit line BL2.

In accordance with the present invention, the row and column lines of the device 100 are driven by voltage drivers that have three different voltage level states, specifically, a low logic level state and two different high logic level states. The two different high logic level states are: (1) full supply VDD high voltage, and (2) reduced high voltage, i.e., less than VDD. Specifically, for the portion of the device 100 shown in FIG. 3, the row lines ROW0, ROW1, ROW2 are driven by the row drivers 120, 122, 124, respectively, and the column lines COL0, COL1, COL2 are driven by the column drivers 126, 128, 130, respectively. The row and column drivers 120, 122, 124, 126, 128, 130 are capable of driving their respective row and column lines to either logic low, full supply VDD high voltage, or reduced high voltage, in accordance with the present invention.

In general, the problem of destructive disturbance of data during read operations in storage cells having only a single bit line that was discussed above is eliminated in the present invention by applying the reduced high voltage level to the row and column lines during the read operation. Because the problem has been overcome by the manner in which the row and column lines are driven, the transistor sizes can be designed for optimal performance for the write operations without worrying about problems associated with the read operation. Thus, the cell size is robust and small.

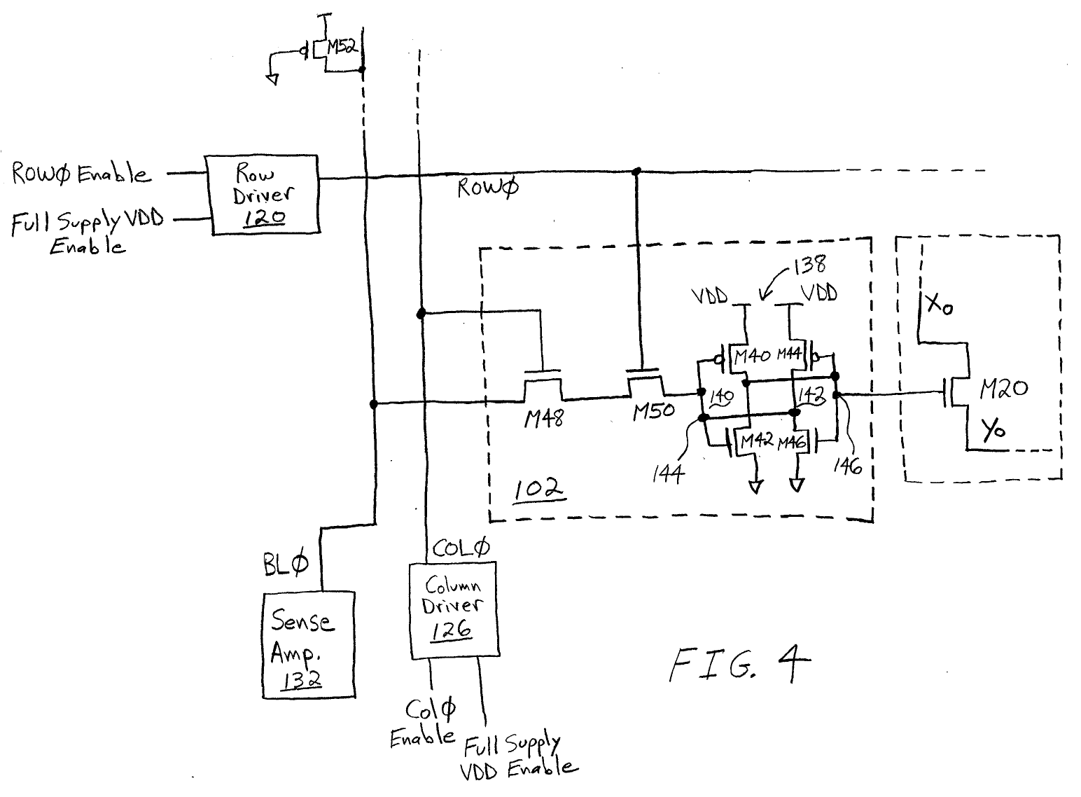

Referring to FIG. 4, the advantages of driving the row and column lines with a reduced high voltage state will now be described in detail. FIG. 4 shows the storage cell 102 in greater detail. The storage cell 102 includes two inverters 140, 142 connected back-to-back to form a CMOS latch 138. The latch 138 includes a first storage node 144 and a second storage node 146. The inverter 140 includes a p-channel transistor M40 and an n-channel transistor M42, and the inverter 142 includes a p-channel transistor M44 and an n-channel transistor M46. The gate of the connection transistor M20 is connected to storage node 146. Two n-channel pass transistors M48, M50 (or “pass gates”) are connected in series to storage node 144. Because the storage cell 102 includes six transistors (i.e., M40, M42, M44, M46, M48, M50), it will be referred to herein as the “six-transistor cell 102”. The configuration of the other storage cells 104-118 in the device 100 is identical to storage cell 102, i.e., all of the storage cells in the device 100 are six-transistors cells.

One purpose of using the series connected pass transistors M48, M50 is to provide row and column selections. Specifically, the gate of the pass transistor M50 is connected to the row line ROW0, and the gate of the pass transistor M48 is connected to the column line COL0. When row line ROW0 and column line COL0 are both activated (i.e., pulled high), the pass transistors M48, M50 both turn on (or “open”) to allow data to be either written to or read from the latch 138 via the bit line BL0. If, however, only one of the row line ROW0 and column line COL0 are activated, data cannot be written to or read from the latch 138 because both of the pass transistors M48, M50 are not turned on.

As mentioned above, there are several types of write operations that may be performed in the device 100. First, when the device 100 is first powered up it is desirable to perform a “memory clear” operation (or cycle). In a typical field programmable logic device, the memory clear operation is performed before the logic configuration starts. One purpose of this operation is to turn off all of the connection transistors M20-M36 so that none of the X signal lines are connected to the Y signal lines. In order to do this, using storage cell 102 as an example, a “1” is written into storage node 144 of the latch 138 so that the latch operation will pull storage node 146 to “0”, thus turning off the connection transistor M20. This operation is generally performed to all of the storage cells 102-118 simultaneously as part of the memory clear operation.

A memory clear write operation is performed on the device 100 by applying a full supply VDD voltage to all of the row lines ROW0, ROW1, ROW2, etc., all of the column lines COL0, COL1, COL2, etc., and all of the bit lines BL0, BL1, BL2, etc. This way, using storage cell 102 as an example, both of the pass transistors M48, M50 will be fully turned on and a “1” will be written from the bit line BL0 to storage node 144.

After the memory clear operation, a user will normally want to selectively program some of the storage cells 102-118 in order to cause certain X signal lines to be connected to certain Y signal lines. This is referred to as the “program connect” part of the configuration operation and involves, using storage cell 102 as an example, writing a “0” to storage node 144 of the latch 138 so that the latch operation will pull storage node 146 to “1”, thus turning on the connection transistor M20. There is also a “program no-connect” part of the configuration operation which is used to selectively program some of the storage cells 102-118 in order to cause certain X signal lines to not be connected to certain Y signal lines. This involves writing a “1” to storage node 144 of the latch 138 so that the latch operation will pull storage node 146 to “0”, thus turning off the connection transistor M20. The program no-connect part of the configuration operation will normally not be necessary after a memory clear operation because the memory clear operation ensures that all connection transistors are turned off. There may be situations, however, such as for example reversing an erroneous program connect operation, where the program no-connect operation is useful.

A configuration program connect write operation is performed by selecting one of the storage cells 102-118 by applying a full supply VDD voltage on the appropriate row and column lines and ground on the appropriate bit line. For example, if the storage cell 102 is selected, a full supply VDD voltage level would be applied to ROW0 and COL0, and the bit line BL0 would be grounded. This way a “0” would be written from the bit line BL0 to storage node 144. A configuration program no-connect write operation is performed by similarly applying a full supply VDD voltage level to ROW0 and COL0, but differs in that a full supply VDD voltage level is also applied to the bit line BL0. Again, the program no-connect operation is similar to a memory clear operation.

Thus, for write operations such as memory clear, configuration program connect, and configuration program no-connect, a full supply VDD voltage level is applied to the gates of the pass transistors M48, M50. The full supply VDD voltage level on the gates of pass transistors M48, M50 make the devices stronger for writing either “0” or “1” to storage node 144.

For read operations, on the other hand, the present invention resolves the problem of destructive disturbance of data during read operations (discussed above) by applying a reduced high voltage level to the gates of the pass transistors M48, M50. The reduced high voltage level makes the pass transistor devices weaker so that the data value stored in the latch 138 is not disturbed. The reduced high voltage level on the gate of the pass transistors M48, M50 will lengthen the read time, but this is not a critical issue in programmable logic applications.

Specifically, during a read operation the bit line BL0 is precharged to a high level with a weak pull-up device, such as a small p-channel transistor M52. The storage cell 102 is then selected by applying a reduced high voltage level to ROW0 and COL0. The reduced high voltage level turns on transistors M48, M50, but not all the way. Thus, the reduced high voltage level applied to the gates of transistors M48, M50 has the effect of weakening them and making them weaker than the pull-down transistor M46. This will prevent the precharged bit line BL0 from disturbing the data stored in the latch 138. For example, if a “0” is stored at storage node 144, the pass transistors M48, M50 having the reduced high voltage level applied to their gates will be weak enough such that the pull-down transistor M46 will be able to pull the precharged bit line BL0 low rather than the pass transistors M48, M50 pulling the storage node 144 up to the level of the precharged bit line BL0. When the bit line BL0 is pulled low, the sense amplifier 132 will then sense the voltage level of the bit line BL0 which is indicative of the data stored at storage node 144.

The low logic level voltage is generally ground (GND) potential, but does not have to be. The reduced high voltage level is greater than the low logic level voltage and less than the full supply VDD high voltage level. By way of example, the reduced high voltage level may be approximately equal to one transistor threshold voltage (VT) less than the full supply VDD high voltage level.

Table I below summarizes the voltage levels that are applied to the bit line, column line and row line of the six-transistor cell 102 for the various write operations and for the read operation.

TABLE I
SIX-TRANSISTOR CELL 102 WRITE AND READ OPERATIONS

| OPERATION | BIT LINE | COLUMN LINE | ROW LINE |
|---|---|---|---|
| Memory Clear (write) | Full Supply VDD | Full Supply VDD | Full Supply VDD |
| Configuration Program | GND | Full Supply VDD | Full Supply VDD |
| Connect (node 144 = “0”) | | | |
| (write) | | | |
| Configuration Program | Full Supply VDD | Full Supply VDD | Full Supply VDD |
| No-Connect (node | | | |
| 144 = “1”)(write) | | | |
| Read | Precharged high | Reduced HIGH | Reduced HIGH |
| | voltage | voltage | voltage |

By way of example, in the six-transistor cell 102, the channel of transistor M40 may have a width of 0.5 μm (micro-meters) and a length of 0.35 μm, the channel of transistor M42 may have a width of 0.9 μm and a length of 0.35 μm, the channel of transistor M44 may have a width of 0.5 μm and a length of 0.35 μm, the channel of transistor M46 may have a width of 0.5 μm and a length of 1.0 μm, the channel of transistor M48 may have a width of 1.1 μm and a length of 0.35 μm, and the channel of transistor M50 may have a width of 1.1 μm and a length of 0.35 μm. It should be well understood, however, that these are merely example transistor sizes and that the transistors may have many different sizes and/or ratios in accordance with the present invention. For example, the transistors sizes may vary depending upon the specific application, semiconductor process used, etc.

The row drivers 120, 122, 124 and the column drivers 126, 128, 130 are the devices that are used to apply either (1) the full supply VDD voltage level, (2) the reduced high voltage level, or (3) a low logic level to their respective row and column lines. Taking row driver 120 as an example, it has a ROW0 Enable input and a Full Supply VDD Enable input. The high or low state of the row line ROW0 is controlled by the ROW0 Enable input. If the high state is to be the full supply VDD voltage level, the Full Supply VDD Enable input is pulled high. If the high state is to be the reduced high voltage level, the Full Supply VDD Enable input is pulled low.

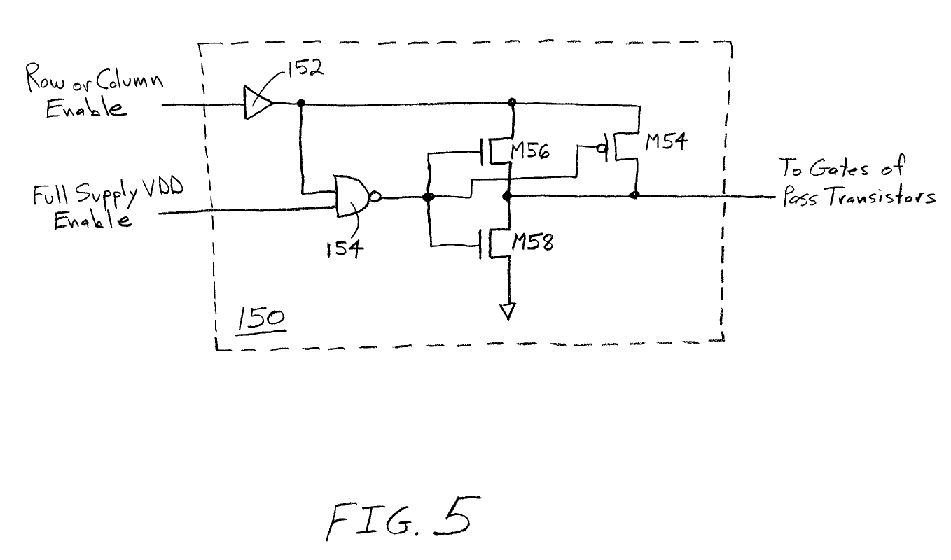

Referring to FIG. 5, there is illustrated a driver circuit 150 that may be used for the row drivers 120, 122, 124 and the column drivers 126, 128, 130. It should be well understood, however, that the driver circuit 150 is just one embodiment of the row and column driver and that many other different types of driver circuits may be used in accordance with the present invention. For example, any other circuit which can provide a reduced voltage can be utilized to serve the same purpose. Furthermore, the level of voltage reduction can be determined by the requirements of noise and/or process margins to ensure a robust read/write operation.

The operation of the driver circuit 150 is as follows. When the Row or Column Enable input is high, and the Full Supply VDD Enable input is high, the output of the NAND gate 154 is driven low which turns off n-channel transistors M56, M58 and turns on p-channel transistor M54. Because the p-channel transistor M54 is turned on, it allows the full power supply voltage VDD to pass to the gates of the pass transistors. On the other hand, when the Row or Column Enable input is high, and the Full Supply VDD Enable input is low, the output of the NAND gate 154 is driven high which turns off transistor M54 and turns on transistors M56, M58. The n-channel transistors M56, M58 serve as a voltage divider to reduce the voltage that is passed to the gates of the pass transistors. The maximum voltage of this divider circuit is VDD-VT, where VT is the threshold voltage of transistors M56, M58. By adjusting the channel width/length ratio of transistor M56 to transistor M58, the reduced high voltage level can vary between ground and one VT below supply voltage.

By way of example, in the driver circuit 150, the channel of transistor M54 may have a width of 10 μm and a length of 0.35 μm, the channel of transistor M56 may have a width of 10 μm and a length of 0.35 μm, and the channel of transistor M58 may have a width of 1.0 μm and a length of 10 μm. Again, it should be well understood that these are merely example transistor sizes and that the transistors may have many different sizes and/or ratios in accordance with the present invention.

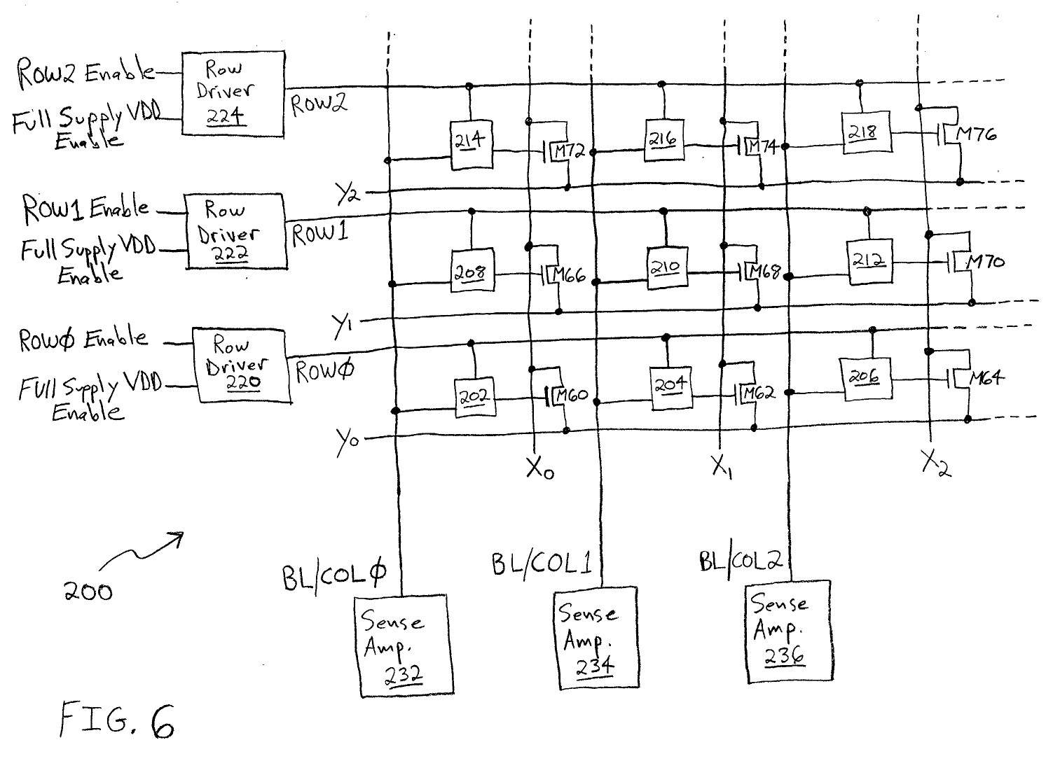

Referring to FIG. 6, there is illustrated another programmable logic device 200 in accordance with the present invention. Similar to the device 100, the device 200 includes an array of several vertical signal lines X0, X1, X2, etc., and several horizontal signal lines Y0, Y1, Y2, etc. The X signal lines may be connected to the Y signal lines by means of connection n-channel transistors M60-M76. The connection transistors M60-M76 are turned on and off by corresponding storage cells 202-218, respectively. Similar to the device 100, the connection transistors M60-M76 and corresponding storage cells 202-218 of the device 200 allow programmable connections to be made between the X signal lines and the Y signal lines such that a user can selectively determine the inputs to an array of logic gates, e.g., AND, OR, etc., that may be connected to either the X or Y signal lines.

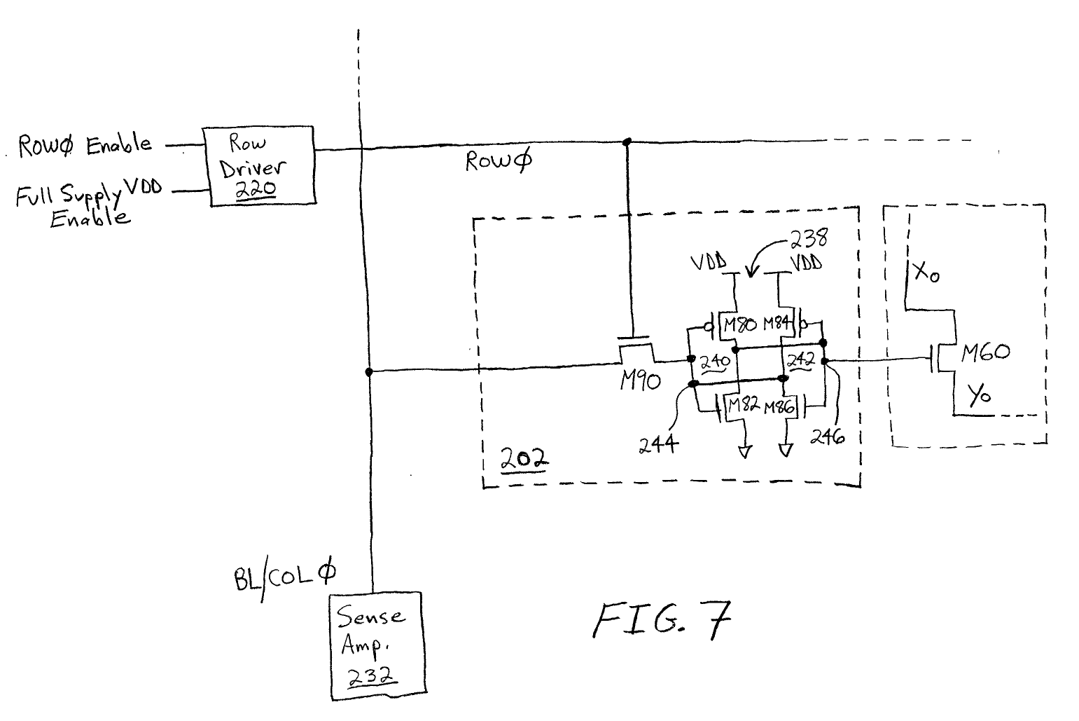

FIG. 7 illustrates the storage cell 202 in greater detail. The storage cell 202 includes two inverters 240, 242 connected back-to-back to form a CMOS latch 238. The latch 238 includes a first storage node 244 and a second storage node 246. The inverter 240 includes a p-channel transistor M80 and an n-channel transistor M82, and the inverter 242 includes a p-channel transistor M84 and an n-channel transistor M86. The gate of the connection transistor M60 is connected to storage node 246. A single n-channel pass transistor M90 (or “pass gate”) is connected to the first storage node 244. Because the storage cell 202 includes five transistors (i.e., M80, M82, M84, M86, M90), it will be referred to herein as the “five-transistor cell 202”. The configuration of the other storage cells 204-218 in the device 200 is identical to storage cell 202, i.e., all of the storage cells in the device 200 are five-transistor cells.

In general, one difference between the five-transistor cell 202 and the six-transistor cell 102 is that with the five-transistor cell 202 a reduced high voltage is applied to the row lines during certain write operations and not just during read operations as with the six-transistor cell 102. As will be discussed below, the reduced high voltage on the row lines during the configuration program connect write operation prevents other storage cells from being disturbed. The five-transistor cell design is robust and smaller in area than the six-transistor cell design.

The single pass transistor M90 is used for row selection. Specifically, the gate of the pass transistor M90 is connected to the row line ROW0. When row line ROW0 is activated (i.e., pulled high), the pass transistor M90 turns on (or “opens”) to allow data to be either written to or read from the latch 238. There is, however, no separate pass transistor for column selection as there is in the six-transistor cell 102 described above. This means that when the row line ROW0 is activated, then entire row of storage cells, i.e., cells 202, 204, 206, etc., are selected and the single pass transistor included in each cell is turned on (or opened).

Because the storage cells 202-218 do not include separate pass transistors for column selection, the bit line and the column line for each column of cells are shared as one bit/column line, resulting in the presence of bit/column lines BL/COL0, BL/COL1, BL/COL2, etc. During read operations, stored data is sensed by sense amplifiers 232, 234, 236. Specifically, the sense amplifier 232 senses data on bit/column line BL/COL0, the sense amplifier 234 senses data on bit/column line BL/COL1, and the sense amplifier 236 senses data on bit/column line BL/COL2.

The operations described above for the six-transistor cell 102, namely, memory clear, configuration program connect, configuration program no-connect, and read, may also be performed for the five-transistor cell 202. Some of these operations, however, are performed somewhat differently for the five-transistor cell 202 in view of the bit and column lines being combined into one line.

The memory clear write operation for the five-transistor cell 202 will be discussed first. Again, the purpose of the memory clear operation is to turn off all of the connection transistors M60-M76 so that none of the X signal lines are connected to the Y signal lines. In order to do this, using storage cell 202 as an example, a “1” is written into storage node 244 of the latch 238 so that the latch operation will pull storage node 246 to “0”, thus turning off the connection transistor M60. This operation is generally performed to all of the storage cells 202-218 simultaneously as part of the memory clear operation, and so all of the connection transistors M60-M76 are turned off.

A memory clear operation is performed on the device 200 (in which all of the storage cells 202-218 are five-transistor cells like cell 202) by applying a full supply VDD voltage to all of the row lines ROW0, ROW1, ROW2, etc., and a full supply VDD voltage to all of the bit/column lines BL/COL0, BL/COL1, BL/COL2, etc. This way, using storage cell 202 as an example, the pass transistor M90 will be fully turned on and a “1” will be written from the bit/column line BL/COL0 to storage node 244. By simultaneously applying full supply VDD voltage to all of the row lines and bit/column lines in the device 200, the latches of all of the storage cells 202-218 are programmed to turn their respective connection transistors M60-M76 off.

As mentioned above, when one of the row lines ROW0, ROW1, or ROW2 is activated, the entire row of storage cells corresponding to that row line is selected and the single pass transistor included in each cell is turned on. This is not an issue for the memory clear operation because during memory clear it is advantageous to write to all of the storage cells simultaneously. The simultaneous selection of an entire row of storage cells does, however, have an impact on the manner in which the configuration operations are performed.

Specifically, during the configuration operations a user may wish to write data to a single storage cell without disturbing other storage cells. With the six-transistor cell 102 discussed above, writing data to a single cell without disturbing other cells is not a problem because the user can select a single cell by activating the appropriate row line and the appropriate column line. Other storage cells in the selected row or column will not be disturbed because they still have at least one of their two pass transistors turned off, or “closed”. With the five-transistor cell 202, however, once the row line ROW0 is activated, the only pass transistor in each of the storage cells in the entire row, i.e., storage cells 202, 204, 206, etc., is turned on. This causes the first node (e.g., node 244) of the latch in each of the storage cells to be exposed to its respective bit/column line, which potentially allows the stored data to be disturbed or destroyed.

As discussed above, the purpose of a configuration program connect write operation is to program a specific storage cell so that its respective connection transistor turns on and connects the respective X and Y signals. This operation typically follows a memory clear operation and, using storage cell 202 as an example, involves driving storage node 244 to a “0” so that the latch operation drives storage node 246 to a “1”, which turns on connection transistor M60.

Therefore, in accordance with the present invention, a configuration program connect write operation is performed on a specific storage cell in the device 200 in the following manner. First, the bit/column line for the specific cell to be programmed is driven to ground and all of the other bit/column lines in the device 200 are precharged to a high level (not necessarily at full supply voltage VDD) with a weak pull-up device, such as a small p-channel transistor. For example, if the specific cell to be programmed is storage cell 202, the bit/column line BL/COL0 is driven to ground (i.e., “0”), and all of the other bit/column lines BL/COL1, BL/COL2, etc., are precharged to a high level. Next, the row line for the specific cell, in this case ROW0, is activated with a reduced high voltage level (rather than a full supply VDD voltage level).

By driving the bit/column line BL/COL0 to ground, storage node 244 will be driven to ground when pass transistor M90 turns on. Because the row line ROW0 is activated with a reduced high voltage level rather than a full supply VDD voltage level, the reduced high voltage level is applied to the gate of the pass transistor M90. Although transistor M90 is not turned on all of the way and is otherwise weaker than it would be if the full supply VDD voltage level were applied to its gate, it is nevertheless turned on hard enough to overcome the pull-up transistor M84 and drive storage node 244 to a “0”. This is because n-channel devices, such as the NMOS pass transistor M90, are inherently good pull-down devices and can easily overcome p-channel devices, such as the PMOS pull-up transistor M84.

One reason for using a reduced high voltage level (rather than a full supply VDD voltage level) on the row line ROW0 is to prevent disturbance of the other, non-selected cells in the same row, i.e., cells 204, 206, etc. These other, non-selected cells will also have the reduced high voltage level applied to the gate of their pass transistor. Furthermore, their corresponding bit/column lines have been precharged to a high level. The issue is whether or not these conditions will disturb the data stored in these cells.

The other, non-selected cells will each be in one of two possible states. First, some cells may still be in the “no-connect” state as a result of the memory clear operation. For these cells it is a simple matter to demonstrate that no data disturbance will occur. Specifically, these cells, as a result of the memory clear operation, have a “1” stored at their first storage node (the storage node corresponding to storage node 244 of cell 202). Although the pass transistors of these cells are turned on by row line ROW0, the bit/column lines associated with these cells are all precharged to a high level as described above. The high level of the bit/column lines does not conflict with the “1” stored at the first storage node of each cell. Therefore, there is no effect on these cells because this is essentially the same state as the memory clear state.

The second possible state of the other, non-selected cells is the “connect” state. Specifically, some of the other cells that are in the same row as the cell that is currently being programmed may have been previously programmed to the “connect” state. For these cells, disturbance is a greater possibility, but by applying the reduced high voltage level (rather than a full supply VDD voltage level) to the row line ROW0, such disturbance is prevented.

Disturbance of cells that have been programmed to the “connect” state is a greater possibility because these cells, as a result of the configuration program connect operation, have a “0” stored at their first storage node (the storage node corresponding to storage node 244 of cell 202). When the row line is activated, the pass transistor of each of these cells is turned on which exposes the first storage node to a bit/column line that has been precharged to a high level. The precharged bit/column line could possibly create a disturbance with the “0” stored at the first storage node. Such disturbance, however, is prevented due to the reduced high voltage of the row line ROW0.

Using storage cell 202 as an example, a “0” will be stored at storage node 244 and the bit/column line BL/COL0 will be precharged to a high level. In order for the data to be disturbed, the storage node 244 must be pulled-up to a “1” by pass transistor M90. However, n-channel devices, such as NMOS transistor M90, are inherently weak pull-up devices. Specifically, an n-channel transistor cannot pull-up a node any higher than one threshold voltage below VDD, or in other words, the highest level is VDD-VT. Furthermore, pass transistor M90 is further weakened by the reduced high voltage of the row line ROW0 that is applied to its gate. This reduces the pull-up capability of pass transistor M90 by an extra ΔV, resulting in pass transistor M90 not being able to pull-up storage node 244 any higher than VDD-VT-ΔV. Therefore, the data stored in latch 238 will not be disturbed because pass transistor M90 is not capable of pulling up storage node 244 to the level of the precharged bit/column line BL/COL0.

When performing the configuration program connect write operation in the device 200, the columns are selected sequentially for programming. This will reduce the chances of a previously programmed cell also being selected by the current row line.

The above-discussion explained how to perform a configuration program connect write operation in the device 200 (which uses five-transistor storage cells). As explained above, the device 100 (which uses six-transistor storage cells) also includes a “program no-connect” part of the configuration operation which is used to selectively program some of the storage cells 102-118 in order to cause certain X signal lines to not be connected to certain Y signal lines. The program no-connect part of the configuration operation will normally not be necessary after a memory clear operation because the memory clear operation ensures that all connection transistors are turned off. It was explained above, however, that there may be situations, such as reversing an erroneous program connect operation, where the program no-connect operation is useful. With respect to the device 200 (which uses five-transistor storage cells), if there is an erroneous program connect operation, a memory clear operation will need to be performed and the program connect operation repeated.

Thus, when performing a write operation on the five-transistor cell 202, the amount of voltage applied to the row line ROW0 depends on the specific write operation being performed. Specifically, for the memory clear operation, the full supply VDD voltage level is applied to the row line ROW0, and for the configuration program connect operation, the reduced high voltage level is applied to the row line ROW0. This is unlike the six-transistor cell 102 discussed above where a full supply VDD voltage level is applied to the gates of the pass transistors M48, M50 for all write operations.

When performing the read operation on the five-transistor cell 202, a reduced high voltage level is applied the row line ROW0. As discussed above, applying a reduced high voltage level to the gates of the pass transistors during read operations prevents the destructive disturbance of data stored in the cell. The reduced high voltage level makes the pass transistor devices weaker so that the data value stored in the latch is not disturbed.

Using storage cell 202 as an example, the read operation for the five-transistor cell will now be described. Specifically, during a read operation the bit/column line BL/COL0 is precharged to a high level with a weak pull-up device. A reduced high voltage level is then applied to the row line ROW0. The reduced high voltage level turns on transistor M90, but not all the way, and actually has the effect of weakening transistor M90 such that it is weaker than the pull-down transistor M86. This will prevent the precharged bit/column line BL/COL0 from disturbing the data stored in the latch 238. For example, if a “0” is stored at storage node 244, the pass transistor M90 having the reduced high voltage level applied to its gate will be weak enough such that the pull-down transistor M86 will be able to pull the precharged bit/column line BL/COL0 low rather than the pass transistor M90 pulling the storage node 244 up to the level of the precharged bit/column line BL/COL0. When the bit/column line BL/COL0 is pulled low, the sense amplifier 232 will sense the voltage level of the bit/column line BL/COL0 which is indicative of the data stored at storage node 244.

Table II below summarizes the voltages levels that are applied to the bit/column line and row line of the five-transistor cell 202, as well as the bit/column lines of neighboring cells, for the various write operations and for the read operation.

TABLE II
FIVE-TRANSISTOR CELL 202 WRITE AND READ OPERATIONS

| | BIT/COLUMN | | ALL OTHER |
|---|---|---|---|
| | LINE OF | ROW LINE OF | BIT/COLUMN |
| OPERATION | SELECTED CELL | SELECTED CELL | LINES |
| Memory Clear (write) | Full Supply VDD | Full Supply VDD | (Full Supply VDD) |
| Configuration Program | GND | Reduced HIGH | Precharged high |
| Connect (node 244 = “0”) | voltage | voltage | |
| (write) | | | |
| Read | Precharged high | Reduced HIGH | Precharged high |
| | voltage | voltage | voltage |

By way of example, in the five-transistor cell 202, the channel of transistor M80 may have a width of 0.5 μm and a length of 0.35 μm, the channel of transistor M82 may have a width of 0.9 μm and a length of 0.35 μm, the channel of transistor M84 may have a width of 0.5 μm and a length of 0.35 μm, the channel of transistor M86 may have a width of 0.5 μm and a length of 1.0 μm, and the channel of transistor M90 may have a width of 1.1 μm and a length of 0.35 μm. Again, it should be well understood that these are merely example transistor sizes and that the transistors may have many different sizes and/or ratios in accordance with the present invention.

The row drivers 220, 222, 224 are the devices that are used to apply either (1) the full supply VDD voltage level, (2) the reduced high voltage level, or (3) a low logic level to their respective row lines ROW0, ROW1, ROW2. The row drivers 220, 222, 224 operate in the same manner as the row drivers 120, 122, 124 and the column drivers 126, 128, 130, and indeed, the same circuitry may be used for the row drivers 220, 222, 224. For example, the driver circuit 150 shown in FIG. 5 may be used for the row drivers 220, 222, 224. It should be well understood, however, that the driver circuit 150 is just one embodiment of the row driver and that many other different types of driver circuits may be used in accordance with the present invention. The primary difference will be in the use of the different voltage levels generated by the row drivers 220, 222, 224. Specifically, for the five-transistor cell 202 the Full Supply VDD Enable input is pulled high only for the memory clear operation and not for the configuration program connect operation. This is different than for the six-transistor cell 102 where the Full Supply VDD Enable input is pulled high for all write operations.

The above-teachings of applying reduced high voltage levels to the gates of the pass transistors of the six-transistor cell 102 and the five-transistor cell 202 have been discussed in connection with programmable logic devices, such as field programmable logic devices. It should be well understood, however, that the above-teachings may also be applied to the use of the six-transistor cell 102 and the five-transistor cell 202, as well as other SRAM cell configurations, in connection with other data storage apparatus, such as for example, digital memories, etc. Thus, the use of reduced high voltage levels with the six-transistor cell 102 and the five-transistor cell 202 may be applied to any device that stores digital data in accordance with the present invention.

It should be understood that various alternatives to the embodiments of the invention described herein may be employed in practicing the invention. It is intended that the following claims define the scope of the invention and that structures and methods within the scope of these claims and their equivalents be covered thereby.

What is claimed is:

1. A data storage apparatus, comprising:
a latch having first and second storage nodes;
a first pass transistor coupled to the first storage node;
a row line coupled to a gate of the first pass transistor; and
a row driver coupled to the row line and configured to drive the row line to three different voltage levels, the three different voltage levels including a low logic level voltage, a full supply high voltage level, and a reduced high voltage level, wherein the reduced high voltage level is greater than the low logic level voltage and less than the full supply high voltage level.

2. A data storage apparatus in accordance with claim 1, wherein the row driver is configured to generate the reduced high voltage level such that it is approximately one transistor threshold voltage less than the full supply high voltage level.

3. A data storage apparatus in accordance with claim 1, further comprising:
a bit/column line coupled to the first pass transistor.

4. A data storage apparatus in accordance with claim 1, further comprising:
a second pass transistor coupled to the first pass transistor;
a column line coupled to a gate of the second pass transistor; and
a column driver coupled to the column line and configured to drive the column line to the three different voltage levels.

5. A data storage apparatus in accordance with claim 4, wherein the row driver and the column driver are configured to generate the reduced high voltage level such that it is approximately one transistor threshold voltage less than the full supply high voltage level.

6. A data storage apparatus in accordance with claim 4, further comprising:
a bit line coupled to the second pass transistor.

7. A data storage apparatus in accordance with claim 1, further comprising:
a connection transistor having a gate that is coupled to the second storage node of the latch.

8. A data storage apparatus, comprising:
a plurality of memory cells arranged into rows and columns, each memory cell including a latch having first and second storage nodes and a first pass transistor coupled to the first storage node;
a plurality of a row lines, each row line being associated with one row of memory cells and being coupled to a gate of the first pass transistor of each memory cell in its respective row; and
a plurality of row drivers, each row driver being coupled to one row line and configured to drive the one row line to three different voltage levels, the three different voltage levels including a low logic level voltage, a full supply high voltage level, and a reduced high voltage level, wherein the reduced high voltage level is greater than the low logic level voltage and less than the full supply high voltage level.

9. A data storage apparatus in accordance with claim 8, wherein the row drivers are configured to generate the reduced high voltage level such that it is approximately one transistor threshold voltage less than the full supply high voltage level.

10. A data storage apparatus in accordance with claim 8, further comprising:
a plurality of bit/column lines, each bit/column line being associated with one column of memory cells and being coupled to the first pass transistor of each memory cell in its respective column.

11. A data storage apparatus in accordance with claim 8, wherein each memory cell further includes a second pass transistor that is coupled to the first pass transistor and wherein the data storage apparatus further comprises:
a plurality of column lines, each column line being associated with one column of memory cells and being coupled to a gate of the second pass transistor of each memory cell in its respective column; and
a plurality of column drivers, each column driver being coupled to one column line and configured to drive the one column line to the three different voltage levels.

12. A data storage apparatus in accordance with claim 11, wherein the row drivers and the column drivers are configured to generate the reduced high voltage level such that it is approximately one transistor threshold voltage less than the full supply high voltage level.

13. A data storage apparatus in accordance with claim 11, further comprising:
a plurality of bit lines, each bit line being associated with one column of memory cells and being coupled to the second pass transistor of each memory cell in its respective column.

14. A data storage apparatus in accordance with claim 13, further comprising:
a plurality of sense amplifiers, each sense amplifier being coupled to one of the bit lines.

15. A data storage apparatus in accordance with claim 8, further comprising:
a plurality of X signal lines, each X signal line being associated with one column of memory cells;
a plurality of Y signal lines, each Y signal line being associated with one row of memory cells; and
a plurality of connection transistors, each connection transistor being associated one memory cell and being coupled to its respective X and Y signal lines and having a gate that is coupled to the second storage node of its respective memory cell.

16. A method of manipulating a memory cell having a latch having a first storage node with first and second series connected pass transistors coupled to the first storage node and a bit line coupled to the second pass transistor, the method comprising:
driving the bit line to a low logic level voltage;
applying a full supply high voltage level to a gate of the first pass transistor and to a gate of the second pass transistor;
applying the low logic level voltage to the gate of the first pass transistor and to the gate of the second pass transistor;
precharging the bit line to a high level; and
applying a reduced high voltage level to the gate of the first pass transistor and to the gate of the second pass transistor, wherein the reduced high voltage level is greater than the low logic level voltage and less than the full supply high voltage level.

17. A method in accordance with claim 16, wherein the reduced high voltage level is approximately equal to one transistor threshold voltage less than the full supply high voltage level.

18. A method in accordance with claim 16, further comprising:
sensing a voltage level of the bit line.

19. A method of manipulating a memory cell having a latch having a first storage node with a first pass transistor coupled to the first storage node and a bit/column line coupled to the first pass transistor, the method comprising:
applying a full supply high voltage level to the bit/column line;
applying the full supply high voltage level to a gate of the first pass transistor;
applying a low logic level voltage to the gate of the first pass transistor;
driving the bit/column line to the low logic level voltage; and
applying a reduced high voltage level to the gate of the first pass transistor, wherein the reduced high voltage level is greater than the low logic level voltage and less than the full supply high voltage level.

20. A method in accordance with claim 19, wherein the reduced high voltage level is approximately equal to one transistor threshold voltage less than the full supply high voltage level.

21. A method in accordance with claim 19, further comprising:
applying the low logic level voltage to the gate of the first pass transistor;
precharging the bit/column line to a high level; and
applying the reduced high voltage level to the gate of the first pass transistor.

22. A method in accordance with claim 21, further comprising:
sensing a voltage level of the bit/column line.
